(19) United States
(12) Patent Application Publication
(10) Pub. No.: US 2026/0073997 A1
(43) Pub. Date: Mar. 12, 2026

(54) SEMICONDUCTOR STORAGE DEVICE

(71) Applicant: Kioxia Corporation, Tokyo (JP)

(72) Inventors: Ayumu IIO, Kawasaki Kanagawa (JP); Norichika ASAOKA, Yokohama Kanagawa (JP); Yuki FUJIMURA, Ota Tokyo (JP)

(73) Assignee: Kioxia Corporation, Tokyo (JP)

(21) Appl. No.: 19/058,170

(22) Filed: Feb. 20, 2025

(30) Foreign Application Priority Data
Sep. 10, 2024 (JP) 2024-156770

(51) Int. Cl. G11C 16/32; G11C 16/30

(52) U.S. Cl. CPC G11C 16/32; G11C 16/30

(57) ABSTRACT

A semiconductor storage device according to the present embodiment includes: a first pad; a clock generation circuit configured to generate a first clock; an output circuit configured to output the first clock through the first pad; a designation circuit configured to designate, as a specific time slot, one of a plurality of time slots generated based on the first clock; and a peak control circuit configured to execute a partial operation that generates a current peak, at a timing corresponding to the specific time slot, when an operation is instructed, in which when the peak control circuit does not execute the partial operation that generates the current peak, within a predetermined period of time after the operation is instructed, the peak control circuit executes the partial operation that generates the current peak, after the predetermined period of time elapses.

### CROSS-REFERENCE TO RELATED APPLICATIONS

This application is based upon and claims the benefit of priority from the prior Japanese Patent Application No. 2024-156770, filed on Sep. 10, 2024, the entire contents of which are incorporated herein by reference.

### FIELD

The embodiments of the present invention relate to a semiconductor storage device.

### BACKGROUND

In recent years, a NAND flash memory has been widely adopted as a semiconductor storage device.

In such a semiconductor storage device, a peak current needs to be suppressed. For suppressing the peak current, a function called TDPPM (Time Division Peak Power Management) that staggers the operation timing among chips in multi-stage components has been considered. However, there is a risk in that if a failure (abnormality) occurs in a signal system for staggering the operation timing, a stuck busy state occurs, resulting in a critical failure.

### BRIEF DESCRIPTION OF THE DRAWINGS

FIG. 1 is a block diagram showing a configuration example of a memory system according to an embodiment;

FIG. 2 is a schematic cross-sectional view for explaining a structure example of a memory device in which memory chips are stacked;

FIG. 3 is a block diagram showing a configuration example of the memory system including a plurality of packages;

FIG. 4 is an explanatory view showing a configuration example of one package;

FIG. 5 is a block diagram showing a configuration example of a nonvolatile memory of the present embodiment;

FIG. 6 is a circuit diagram showing a part of a configuration of an input/output circuit;

FIG. 7 is a circuit diagram showing a part of a configuration of a logic control circuit;

FIG. 8 is an explanatory view for explaining generation of a peak enable signal;

FIG. 9 is an explanatory view for explaining generation of a peak enable signal;

FIG. 10 is an explanatory view for explaining a peak operation control;

FIG. 11 is a view showing an example of TDPPM of a comparative example;

FIG. 12 is a block diagram showing a configuration example of the nonvolatile memory of the present embodiment;

FIG. 13 is a view showing an example of TDPPM of the present embodiment; and

FIG. 14 is a view showing an example of paths of signals of the present embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes: a first pad; a clock generation circuit configured to generate a first clock; an output circuit configured to output the first clock through the first pad; a designation circuit configured to designate, as a specific time slot, one of a plurality of time slots generated based on the first clock; and a peak control circuit configured to execute a partial operation that generates a current peak, at a timing corresponding to the specific time slot, when an operation is instructed, in which when the peak control circuit does not execute the partial operation that generates the current peak, within a predetermined period of time after the operation is instructed, the peak control circuit executes the partial operation that generates the current peak, after the predetermined period of time elapses.

### First Embodiment

In the present embodiment, in a semiconductor storage device having a multi-chip configuration, a specific chip is designated as a leader and the other chips as followers, and all the chips use a clock generated by the leader so as to enable operations of the chips to be controlled, thereby controlling a peak current.

### Configuration of Memory System

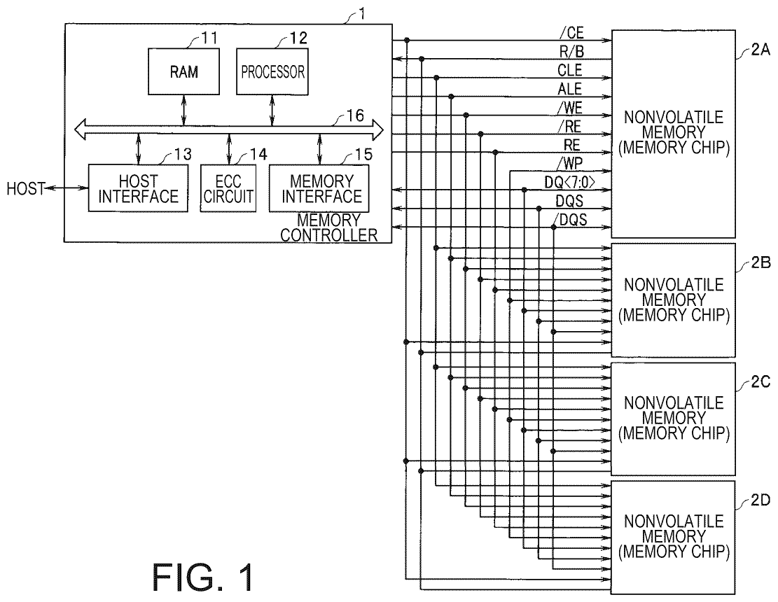

FIG. 1 is a block diagram showing a configuration example of a memory system according to an embodiment. The memory system of the present embodiment includes a memory controller 1 and one or more NAND nonvolatile memories. FIG. 1 shows an example in which four NAND nonvolatile memories 2A to 2D are included. Hereafter, when the four NAND nonvolatile memories 2A to 2D do not need to be distinguished from each other, the memories are represented as NAND nonvolatile memories 2. Further, the NAND nonvolatile memories may be simply referred to as nonvolatile memories. The memory system may be connected to a host (not shown). The host is, for example, electronic equipment such as a personal computer or a mobile terminal. Each nonvolatile memory 2 is, for example, formed as a chip. In the following descriptions, the nonvolatile memories 2 may also be described as memory chips 2. The memory chips 2 are stacked in a memory device in some cases.

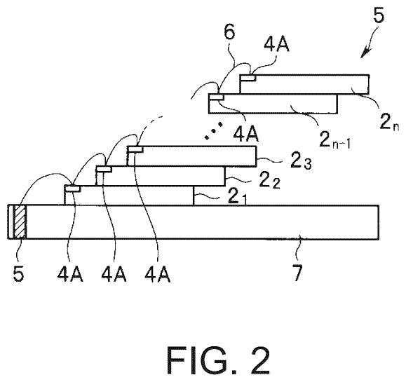

FIG. 2 is a schematic cross-sectional view for explaining a structure example of a memory device in which the memory chips 2 are stacked. FIG. 2 shows an example in which n memory chips 2₁, 2₂, . . . , 2n are stacked on a wiring substrate 7. When the n memory chips 2₁, 2₂, . . . , 2n do not need to be distinguished from each other, the memory chips are referred to as memory chips 2. The memory device 5 achieves a high memory density and a large storage capacity, with a plurality of memory chips 2.

The plurality of memory chips 2 are stacked on a substrate so as to reduce the size (area) of a package. The stacked memory chips 2 are connected to each other, using a bonding wire 6, a through electrode, or the like.

For example, as shown in FIG. 2, when an upper memory chip 2ₙ and a lower memory chip 2ₙ₋₁ are connected to each other using the bonding wire 6, the upper memory chip 2ₙ is stacked on the lower memory chip 2ₙ₋₁ so as to be staggered relative to the lower memory chip 2ₙ₋₁ by a given interval. As a result, a pad 4A provided on the lower memory chip 2 ₙ₋₁ is exposed without being covered by the upper memory chip 2ₙ.

For example, the pads 4A of the memory chips 2 are connected to the common bonding wire 6 and connected to a terminal 5 of the wiring substrate 7. In this manner, the plurality of memory chips 2 share wiring for inputting/outputting each signal. Therefore, the plurality of memory chips 2 cannot individually drive a data line. Accordingly, among the plurality of nonvolatile memories (and a controller) that share the data line, only one chip can output data.

### Peak Current

When the multi-chip configuration as in FIG. 2 is adopted, the timings of cell operations of the plurality of memory chips 2 coincide with each other in some cases. In this case, current peaks may be concurrently generated in the memory chips 2 in accordance with the cell operations, which could occasionally generate the total peak current more than expected. Thus, TDPPM (Time Division Peak Power Management) is occasionally adopted that manages a period in which the current peak is allowed to be generated for each memory chip 2.

However, in this management method, the cell operations need to be managed by providing a common clock to all the memory chips 2. In the conventional TDPPM, a controller provides a common clock to all the memory chips 2. As a result, there is a drawback in that terminals or wiring for providing the clock increase, thereby increasing a load on the controller.

Thus, a technique of managing the peak generation period may also be considered that uses an internal clock generated inside each memory chip 2. However, in this case, the internal clocks need to be synchronized with each other for each predetermined period of time, and in a long-period operation, reliable peak current management cannot be performed.

### Leader and Followers

Thus, in the present embodiment, a specific memory chip (hereinafter, also referred to as a leader) among all the memory chips 2 is caused to generate a clock, and the clock generated by the leader is provided to all the other memory chips (hereinafter, also referred to as followers) using a terminal connected in common to all the memory chips 2, so as to enable TDPPM in which the generation period of the peak current is stably managed.

In FIG. 1, the nonvolatile memory (memory chip) 2 is a semiconductor storage device that stores data in a nonvolatile manner. As shown in FIG. 1, the memory controller 1 and each nonvolatile memory 2 are connected to each other via a NAND bus. The memory controller 1 controls writing data to the nonvolatile memory 2 in accordance with a write request from a host. Further, the memory controller 1 controls reading data from the nonvolatile memory 2 in accordance with a read request from the host. The memory controller 1 includes an RAM (Random Access Memory) 11, a processor 12, a host interface 13, an ECC (Error Check And Correct) circuit 14, and a memory interface 15. The RAM 11, the processor 12, the host interface 13, the ECC circuit 14, and the memory interface 15 are connected to each other via an internal bus 16.

The host interface 13 outputs a request received from the host, write data which is user data, and the like to the internal bus 16. Further, the host interface 13 transmits user data read from the nonvolatile memory 2, a response from the processor 12, and the like to the host.

The memory interface 15 controls processing of writing to and reading from the nonvolatile memory 2 of user data and the like based on an instruction from the processor 12.

The processor 12 comprehensively controls the memory controller 1. The processor 12 is, for example, a CPU (Central Processing Unit), an MPU (Micro Processing Unit), or the like. Upon receipt of a request from the host via the host interface 13, the processor 12 performs control in accordance with the request. For example, the processor 12 instructs the memory interface 15 to write user data and parity to the nonvolatile memory 2 in accordance with the request from the host. Further, the processor 12 instructs the memory interface 15 to read user data and parity from the nonvolatile memory 2 in accordance with the request from the host.

The processor 12 determines a storage area (hereinafter, referred to as a memory area) in the nonvolatile memory 2, for user data accumulated in the RAM 11. The user data is stored in the RAM 11 via the internal bus 16. The processor 12 determines the memory area for page unit data as a write unit, that is, page data. In the present specification, the user data stored in one page of the nonvolatile memory 2 is defined as unit data. The unit data is, for example, encoded and stored as a codeword in the nonvolatile memory 2.

Note that encoding is not essential. The memory controller 1 may store the unit data without encoding it in the nonvolatile memory 2, but FIG. 1 shows, as a configuration example, the configuration in which encoding is performed. When the memory controller 1 does not perform encoding, the page data corresponds to the unit data. Further, one codeword may be generated based on one unit data, or one codeword may be generated based on divided data obtained by dividing the unit data. Further, one codeword may be generated using a plurality of unit data.

The processor 12 determines, for each unit data, the memory area of the nonvolatile memory 2 that is a write destination. A physical address is allocated to the memory area of the nonvolatile memory 2. The processor 12 manages the memory area that is the write destination of the unit data, using the physical address. The processor 12 designates the physical address of the determined memory area and instructs the memory interface 15 to write the user data to the nonvolatile memory 2. The processor 12 manages the correspondence between a logical address (which is a logical address managed by the host) of user data and the physical address. Upon receipt of a read request including a logical address from the host, the processor 12 specifies the physical address that corresponds to the logical address, and designates the physical address and instructs the memory interface 15 to read the user data.

The ECC circuit 14 encodes user data stored in the RAM 11 and generates a codeword. Further, the ECC circuit 14 decodes a codeword read from the nonvolatile memory 2. The RAM 11 temporarily stores user data received from the host until the user data is stored in the nonvolatile memory 2, and temporarily stores data read from the nonvolatile memory 2 until the data is transmitted to the host. The RAM 11 is, for example, a general-purpose memory such as an SRAM (Static Random Access Memory), a DRAM (Dynamic Random Access Memory), or the like.

FIG. 1 shows the configuration example in which the memory controller 1 includes both the ECC circuit 14 and the memory interface 15. However, the ECC circuit 14 may be built in the memory interface 15. Alternatively, the ECC circuit 14 may be built in the nonvolatile memory 2.

Upon receipt of a write request from the host, the memory controller 1 operates as follows. The processor 12 causes the RAM 11 to temporarily store write data. The processor 12 reads the data stored in the RAM 11 and inputs the read data to the ECC circuit 14. The ECC circuit 14 encodes the input data and provides the codeword to the memory interface 15. The memory interface 15 writes the input codeword to the nonvolatile memory 2.

Upon receipt of a read request from the host, the memory controller 1 operates as follows. The memory interface 15 provides a codeword read from the nonvolatile memory 2 to the ECC circuit 14. The ECC circuit 14 decodes the input codeword and stores the decoded data in the RAM 11. The processor 12 transmits the data stored in the RAM 11 to the host via the host interface 13.

The processor 12 of the memory controller 1 controls the memory interface 15 to transmit a signal DQ<7:0> and data strobe signals DQS and /DQS to the nonvolatile memory 2. The signal DQ<7:0> transmitted from the memory controller 1 to the nonvolatile memory 2 includes a command, an address, and data. The data includes SetFeature data as set values for various operation modes of the nonvolatile memory 2, and write data to be written to a memory cell array 23 described later. The data strobe signals DQS and /DQS are synchronous control signals that are generated in sync with data transfer and that indicate read and write timings.

The processor 12 controls the memory interface 15 to transmit a chip enable signal /CE, a signal CLE, a signal ALE, a signal /WE, and read enable signals RE and /RE to the nonvolatile memory 2. The signal /CE is a signal for bringing each nonvolatile memory 2 into an operational state. The write enable signal /WE is a signal permitting writing, and the nonvolatile memory 2 fetches a command or an address by receiving the signal /WE. That is, the signal /WE may be referred to as a fetch signal. The command latch enable signal CLE is a signal permitting command latch, and the address latch enable signal ALE is a signal permitting address latch.

A signal with a symbol “/” attached at its head indicates an active row or negative logic. That is, a signal without the symbol “/” attached at its head becomes active at an “H” level, while a signal with the symbol “/” attached at its head becomes active at an “L” level.

Meanwhile, the nonvolatile memory 2 receives various signals from the memory controller 1 and transmits the signal DQ<7:0> and the data strobe signals DQS and /DQS to the memory controller 1, via an input/output circuit 22 described later. Further, the nonvolatile memory 2 transmits a signal R/B to the memory controller 1. The ready-busy signal R/B indicates whether the nonvolatile memory 2 is in a ready state available for receiving a command from the outside or in a busy state unavailable for receiving a command from the outside.

Note that the memory controller 1 can output a write protect signal /WP, but in the present embodiment, since the memory chips 2 are connected in common to a terminal (pad) /WP used for transmitting the write protect signal /WP, the write protect signal /WP is not received in the memory chips 2.

The four memory chips 2 are occasionally packaged. In the example of FIG. 1, one memory controller 1 controls the four memory chips 2 included in one package. Further, one memory controller 1 controls the memory chips 2 included in a plurality of packages in some cases.

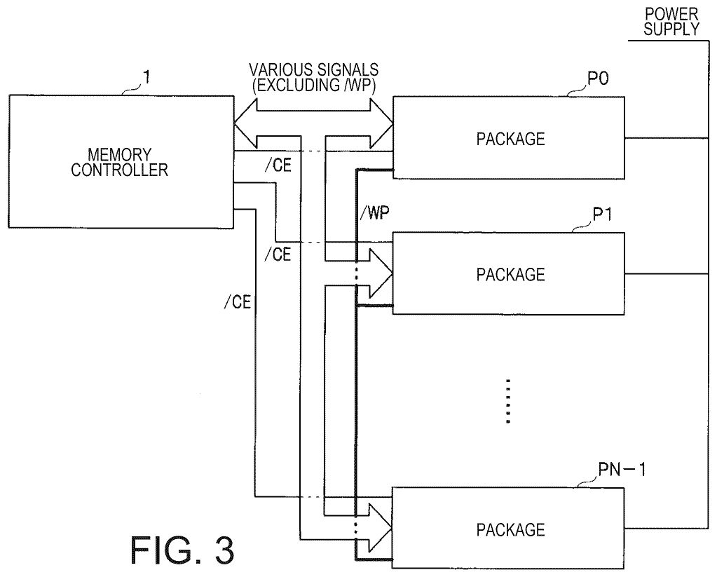

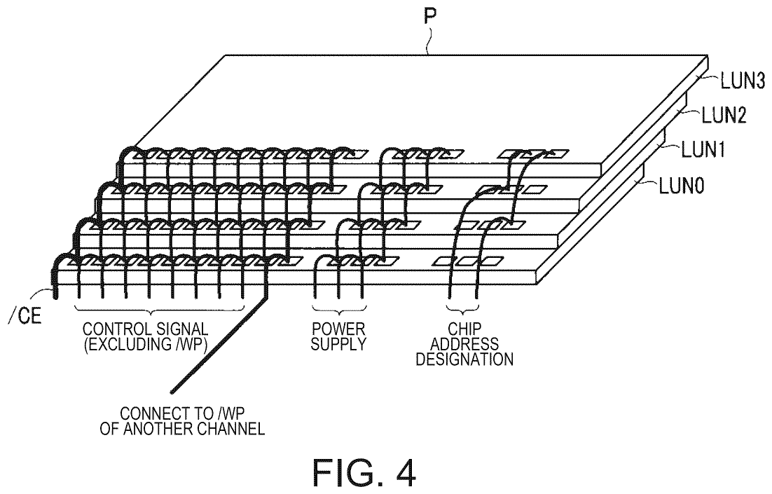

FIG. 3 is a block diagram showing the example of this case. Further, FIG. 4 is an explanatory view showing a configuration example of one package.

As shown in FIG. 3, the memory controller 1 and packages P0 to PN−1 (hereinafter, referred to as packages P when the packages do not need to be distinguished from each other) are connected to each other via a NAND bus, and signals except for the write protect signal /WP are transmitted between the memory controller 1 and the memory chips 2 in the packages P. Further, between the memory controller 1 and each package P, wiring for individually providing the chip enable signal /CE is provided. A power supply voltage is supplied to each package P from a predetermined power supply.

In the present embodiment, a terminal /WP for receiving the write protect signal /WP is used to connect the memory chips 2 to each other in each package P, as described above.

As shown in FIG. 4, each package P includes a plurality of memory chips 2 (LUN0-LUN3). Note that although FIG. 4 shows an example in which each package P is configured with four memory chips 2, the number of memory chips 2 included in the package P is not limited. As shown in FIG. 4, the memory chips 2 in each package P share various types of wiring for providing the various signals, except for the write protect signal /WP, and power. That is, in the package P, a group that share the signals ALE, CLE, DQ, DQS, /DQS, /WE, /RE, RE, and the like and to which these signal lines are provided is also referred to as a channel. That is, in the example of FIG. 4, a channel is configured with one package P. In the example of FIG. 4, one chip enable signal /CE is only provided in the package P, but one package P has a group driven by a plurality of chip enable signals /CE in some cases.

A chip address is used for selecting the memory chips 2 in the group driven by one chip enable signal /CE. In the example of FIG. 4, since four memory chips 2 are selected by the chip enable signal /CE, the memory chips 2 can be specified by a 2-bit chip address. Note that the memory chip 2 specified by the chip address is referred to as a LUN. FIG. 4 shows an example in which four LUNs of LUN0 to LUN3 are included in one package P.

### Configuration of Nonvolatile Memory

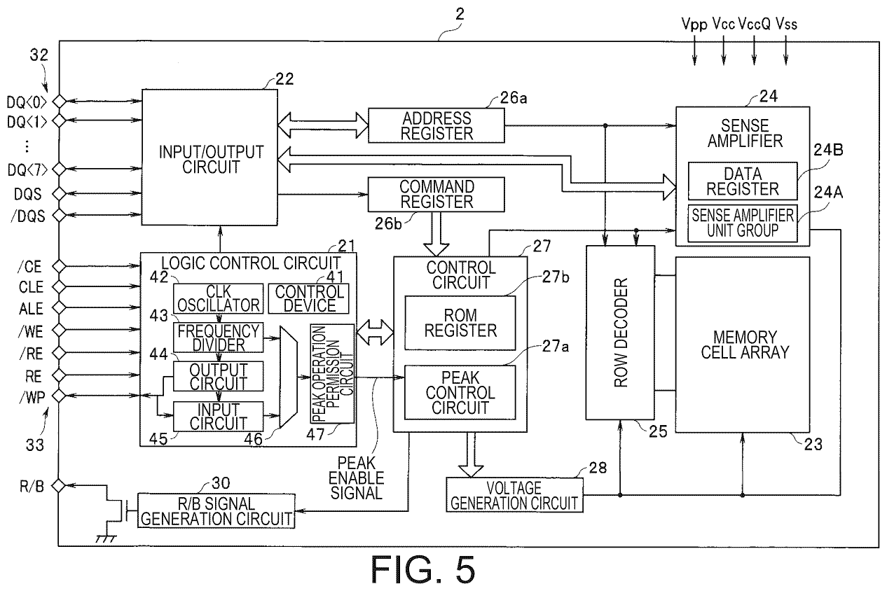

FIG. 5 is a block diagram showing a configuration example of the nonvolatile memory of the present embodiment. The nonvolatile memory (memory chip) 2 includes a logic control circuit 21, the input/output circuit 22, the memory cell array 23, a sense amplifier 24, a row decoder 25, an address register 26a, a command register 26b, a control circuit 27, a voltage generation circuit 28, an R/B signal generation circuit 30, an input/output pad group 32, and a logic control pad group 33.

The memory cell array 23 includes a plurality of blocks (memory blocks). The plurality of blocks BLK each include a plurality of memory cell transistors (memory cells). In the memory cell array 23, a plurality of bit lines, a plurality of word lines, a source line, and the like are provided for controlling voltages applied to the memory cell transistors.

The input/output pad group 32 transmits/receives each signal including data to/from the memory controller 1, and thus includes a plurality of terminals (pads) that corresponds to the signal DQ<7:0> and the data strobe signals DQS and /DQS.

The logic control pad group 33 transmits/receives each signal to/from the memory controller 1, and thus includes a plurality of terminals (pads) that corresponds to the chip enable signal /CE, the command latch enable signal CLE, the address latch enable signal ALE, the write enable signal /WE, and the read enable signals RE and /RE.

In the present embodiment, the terminal (pad) /WP corresponding to the write protect signal /WP is used for transmitting a clock CK between a leader and followers.

The logic control circuit 21 and the input/output circuit 22 are connected to the memory controller 1 via a NAND bus. The logic control circuit 21 receives an external control signal (for example, the chip enable signal /CE, the command latch enable signal CLE, the address latch enable signal ALE, the write enable signal /WE, and the read enable signals RE and /RE) from the memory controller 1 via the NAND bus. Further, the R/B signal generation circuit 30 transmits the ready-busy signal R/B to the memory controller 1 via the NAND bus.

The address register 26a stores addresses. The command register 26b stores commands. The address register 26a and the command register 26b are configured with, for example, an SRAM.

Various operation power supplies, such as power supply voltages Vcc, VccQ, and Vpp, and a ground voltage Vss are supplied to the nonvolatile memory 2 from the outside. Note that the power supply voltage Vcc is a circuit power supply voltage that is generally supplied from the outside as an operation power supply and is, for example, a voltage of around 2.5 V. The power supply voltage VccQ is, for example, a voltage of 1.2 V. The power supply voltage VccQ is used when a signal is transmitted/received between the memory controller 1 and the nonvolatile memory 2. The power supply voltage Vpp is a power supply voltage higher than the power supply voltage Vcc and is, for example, a voltage of 12 V.

The control circuit 27 receives a command from the command register 26b and controls each part of the nonvolatile memory 2 in accordance with a sequence of the command.

The voltage generation circuit 28 is controlled by the control circuit 27 to receive a power supply voltage from the outside of the nonvolatile memory 2 and to generate a plurality of voltages required for write operation, read operation, and erase operation, using the power supply voltage. The voltage generation circuit 28 supplies the generated voltages to the memory cell array 23, the sense amplifier 24, the row decoder 25, and the like.

The row decoder 25 receives a row address from the address register 26a and decodes the row address. The row decoder 25 performs an operation of selecting a word line based on the decoded row address. Then, the row decoder 25 transfers, to a selected block, a plurality of voltages required for the write operation, the read operation, and the erase operation.

A sense amplifier unit group 24A of the sense amplifier 24 receives a column address from the address register 26a and decodes the column address. The sense amplifier unit group 24A selects any of the bit lines based on the decoded column address. Further, during reading data, the sense amplifier unit group 24A detects and amplifies data read from a memory cell transistor into the bit line. Furthermore, during writing data, the sense amplifier unit group 24A transfers the write data to the bit line.

The sense amplifier 24 includes a data register 24B, and during reading data, the data register 24B stores data detected by the sense amplifier unit group 24A and serially transfers the stored data to the input/output circuit 22. Further, during writing data, the data register 24B stores data serially transferred from the input/output circuit 22 and transfers the stored data to the sense amplifier unit group 24A. The data register 24B is configured with an SRAM or the like.

The input/output circuit 22 is controlled by the logic control circuit 21 to transmit/receive the signal DQ (for example, DQ0 to DQ7) and signals DQS, /DQS to/from the memory controller 1 via the NAND bus.

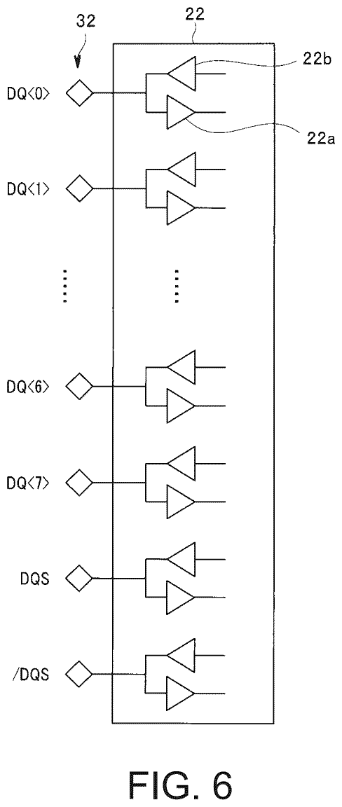

FIG. 6 is a circuit diagram showing a part of a configuration of the input/output circuit 22. As shown in FIG. 6, the input/output circuit 22 includes an input receiver 22a and an output driver 22b for each terminal of the input/output pad group 32. The input receiver 22a receives a signal input via each terminal and the output driver 22b transmits a signal to be output via each terminal.

The input/output circuit 22 is configured such that when the signal DQ is provided together with the signals DQS and /DQS, the input/output circuit 22 receives the signal DQ as data in sync with the signals DQS and /DQS. Further, in response to a signal RE that is provided to the logic control circuit 21, the input/output circuit 22 transmits data read from the memory cell array 23 as the signal DQ to the memory controller 1, together with the signals DQS and /DQS.

The input/output circuit 22 is controlled by the logic control circuit 21 to enable a signal transfer in response to the signal /E or a signal transfer in response to the signals DQS and /DQS. The input/output circuit 22 is controlled by the logic control circuit 21 to output received various signals to the address register 26a or the command register 26b.

The logic control circuit 21 determines whether the signal transfer to/from the own nonvolatile memory 2 is designated by the memory controller 1, using an address Cadd. The logic control circuit 21 controls the input/output circuit 22 in response to the signal CLE to enable a command received as the signal DQ to be output to the command register 26b. The logic control circuit 21 controls the input/output circuit 22 in response to the signal ALE to enable an address received as the signal DQ to be output to the address register 26a. The logic control circuit 21 causes the input/output circuit 22 to output the received signal to each component in sync with the signal /WE so as to enable writing.

When a command is provided from the command register 26b, the control circuit 27 analyzes the command and controls the logic control circuit 21 based on the analysis result.

### Peak Operation Control

In the present embodiment, the control circuit 27 executes peak management under TDPPM when a peak control start command is input.

The memory cell array 23 is provided with an area (hereinafter, referred to as a ROM area) that stores system information for setting the system operation. In the present embodiment, peak management information for TDPPM is also stored in the ROM area. In TDPPM, a slot which is a time slot (hereinafter, simply referred to as a slot) in sync with the clock CK and in which a number (hereinafter, referred to as a slot number) designating the slot circulates in a cycle of a predetermined number of slots (hereinafter, referred to as the total number of slots) is set. The management (peak operation control) of the peak current is performed by specifying a slot in which the peak current is allowed to be generated, for each memory chip 2.

The peak management information stored in the ROM area includes information on a frequency division cycle for setting a clock frequency used for the control of TDPPM, information on the total number of slots indicating one cycle of a slot number, information on a slot allocation number for designating a slot in which the current peak is allowed to be generated, and leader-follower information indicating a leader or a follower. Note that the information on the slot allocation number and the leader-follower information are set for each memory chip 2.

The system information including the peak management information is read by a power-ON read executed immediately after the memory system or the memory chip 2 starts. The memory chip 2 controls write operation and read operation of user data using the system information and the peak management information read from the ROM area by the power-ON read.

The control circuit 27 includes a peak control circuit 27a and a ROM register 27b. The ROM register 27b stores the system information and the peak management information read by the power-ON read. The peak control circuit 27a controls a timing at which the peak of the current flowing in the memory chip 2 is generated. That is, the peak control circuit 27a suspends the peak operation until the input of a peak enable signal that permits execution of a partial operation (hereinafter, referred to as a peak operation), which generates the current peak, of the operations of the memory chip 2. For example, the read operation includes a channel clean operation as the partial operation (peak operation) to be a target of the current peak operation. For the peak operation such as the channel clean operation, the peak control circuit 27a performs control (peak operation control) of waiting for an input of the peak enable signal and executing the peak operation, thereby preventing the peak current from increasing more than expected. Note that the peak control circuit 27a may execute the peak operation at a timing corresponding to the timing at which the peak enable signal is input, by appropriately adjusting the timing.

The control circuit 27 outputs the peak management information stored in the ROM register 27b to the logic control circuit 21 to cause the peak enable signal to be generated.

### Configuration of Logic Control Circuit for Peak Operation Control

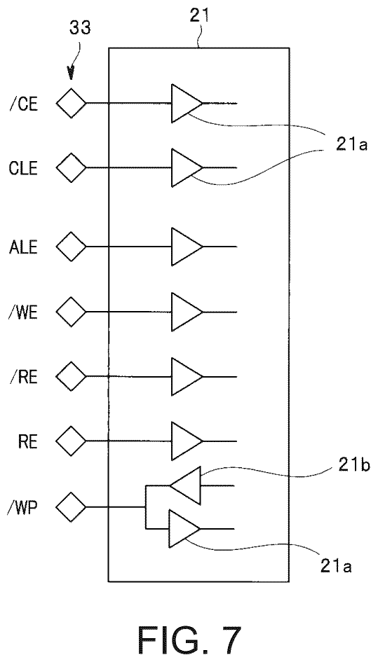

FIG. 7 is a circuit diagram showing a part of a configuration of the logic control circuit 21. The logic control circuit 21 includes an input receiver 21a for each terminal of the logic control pad group 33. The input receiver 21a receives signals input via each terminal. Further, the logic control circuit 21 includes an output driver 21b corresponding to the terminal /WP of the logic control pad group 33. The output driver 21b transmits signals to be output via each terminal. Note that as will be described later, the input receiver 21a corresponding to the terminal /P receives a clock CK transmitted from the terminal /WP of another memory chip 2, and the output driver 21b transmits a clock CK to be provided to another memory chip 2 via the terminal /WP.

As shown in FIG. 5, the logic control circuit 21 includes a control device 41, a clock (CLK) oscillator 42, a frequency divider 43, an output circuit 44, an input circuit 45, a multiplexer 46, and a peak operation permission circuit 47, in addition to the circuit component for controlling the input/output circuit 22. Note the input circuit 45 corresponds to the input receiver 21a of FIG. 7, and the output circuit 44 corresponds to the output driver 21b of FIG. 7. The control device 41 controls the entire logic control circuit 21. The control device 41 may be configured with a processor using a CPU, an FPGA (Field Programmable Gate Array), or the like. The control device 41 may operate and perform control of each component in accordance with programs stored in a memory (not shown), or may implement a part or all of the functions by means of a hardware electronic circuit. The control device 41 controls each component based on the peak management information.

The clock oscillator 42 generates a clock having a predetermined frequency and outputs the generated clock to the frequency divider 43. The control device 41 designates a frequency division number based on the information on the frequency division cycle in the peak management information to the frequency divider 43, and the frequency divider 43 generates a clock CK by dividing the frequency of the clock output from the clock oscillator 42. The frequency divider 43 outputs the clock CK obtained by dividing the frequency to the output circuit 44 and the multiplexer 46. A clock generation circuit is configured with the clock oscillator 42 and the frequency divider 43.

The output circuit 44 is controlled by the control device 41 to output the clock CK from the frequency divider 43 to the terminal /WP. Further, the input circuit 45 is controlled by the control device 41 to receive the clock CK input via the terminal /WP. The input circuit 45 outputs the received clock CK to the multiplexer 46.

The multiplexer 46 is controlled by the control device 41 to select either the clock CK from the frequency divider 43 or the clock CK received by the input circuit 45 and to output the selected clock CK to the peak operation permission circuit 47.

In the present embodiment, the control device 41 determines whether the memory chip is designated as a leader or a follower, based on the leader-follower information in the peak management information stored in the ROM register 27b. The control device 41 of the memory chip designated as a leader operates the clock oscillator 42, the frequency divider 43, the output circuit 44, the multiplexer 46, and the peak operation permission circuit 47. Further, the control device 41 of the memory chip designated as a follower operates the input circuit 45, the multiplexer 46, and the peak operation permission circuit 47.

That is, in the logic control circuit 21 of the memory chip designated as a leader, the clock CK is output to each memory chip 2 connected to the terminal /WP via the terminal /WP through the output circuit 44. Further, in the logic control circuit 21 of the memory chip designated as a follower, the input circuit 45 receives the clock CK output from another memory chip 2 via the terminal /WP. The control device 41 of the memory chip designated as a leader causes the multiplexer 46 to select the clock CK output by the frequency divider 43 and provides the selected clock CK to the peak operation permission circuit 47, and the control device 41 of the memory chip designated as a follower causes the multiplexer 46 to select the clock CK output by the frequency divider 43 and provides the selected clock CK to the peak operation permission circuit 47.

In the present embodiment, the peak operation permission circuit 47 as a designation circuit is controlled by the control device 41 to generate the peak enable signal for controlling the timing at which the peak current is generated. For example, the peak operation permission circuit 47 may be configured with a shift register. The peak operation permission circuit 47 recognizes a current slot number, by counting the clock CK input via the multiplexer 46 while resetting a count value based on the information on the total number of slots. The peak operation permission circuit 47 is provided with a slot allocation number from the control device 41 and generates the peak enable signal in sync with the timing at which the current slot number reaches the slot allocation number. The peak operation permission circuit 47 outputs the generated peak enable signal to the peak control circuit 27a.

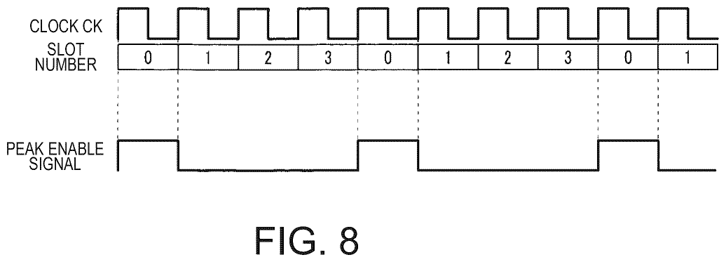

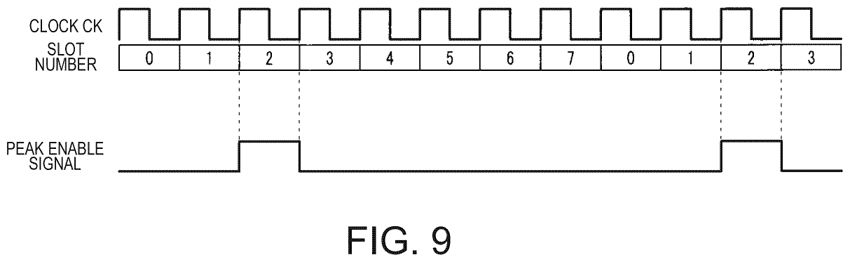

FIG. 8 and FIG. 9 are explanatory views for explaining the generation of the peak enable signal.

FIG. 8 is an example in which the total number of slots is 4 and the slot allocation number set for a specific memory chip 2 is 0. Further, FIG. 9 is an example in which the total number of slots is 8 and the slot allocation number set for a specific memory chip 2 is 2.

As described above, the peak operation permission circuit 47 obtains a current slot number, by counting the clock CK while resetting a count value based on the total number of slots. That is, in the example of FIG. 8, slot numbers 0, 1, 2, 3, 0, 1, . . . are obtained. The peak operation permission circuit 47 generates the peak enable signal at the timing at which the current slot number reaches the slot allocation number. In the example of FIG. 8, since the slot allocation number is 0, the peak enable signal at an H level is obtained each time the count value becomes 0.

Further, in the example of FIG. 9, slot numbers 0, 1, 2, 3, 4, 5, 6, 7, 0, 1, . . . are obtained. In the example of FIG. 9, since the slot allocation number is 2, the peak enable signal at an H level is obtained each time the count value becomes 2.

### Operation

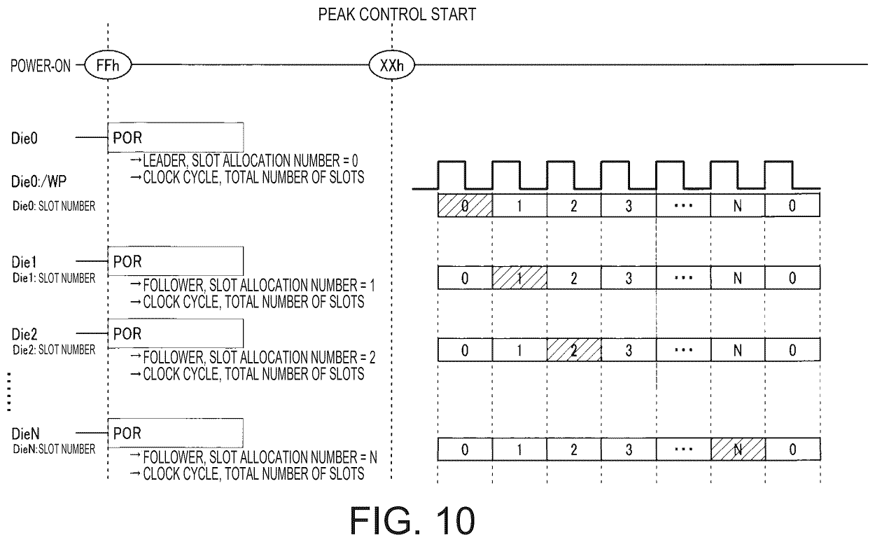

Next, the operation of the embodiment configured as described above will be described with reference to FIG. 10. FIG. 10 is an explanatory view for explaining the peak operation control.

FIG. 10 represents time by the lateral axis and indicates a command from the memory controller 1 and a peak operation period of the peak operation control of each of N+1 memory chips 2 (memory chips Die0 to DieN in FIG. 10). Note that the example of FIG. 10 includes, as the peak management information stored in the ROM area of the memory cell array 23, the frequency division cycle, the total number of slots being N, the slot allocation number for each of the memory chips Die0 to DieN, and information indicating that the memory chip Die0 is a leader and the other memory chips Die1 to DieN are followers.

After the power is turned ON, each of the memory chips Die0 to DieN receives a power-ON read command FFh transmitted from the memory controller 1. The power-ON read command FFh is not accompanied by the chip address Cadd. That is, upon receipt of the command FFh, each of the memory chips Die0 to DieN executes the power-ON read operation, irrespective of their chip addresses. Upon receipt of the command FFh, each of the memory chips Die0 to DieN reads the system information and the peak management information from the ROM area of each memory cell array 23, and stores the read information in the ROM register 27b of the control circuit 27. A command that is not accompanied by the chip address Cadd, such as the power-ON read command FFh, is also referred to as a broadcast command. Meanwhile, a command that is accompanied by the chip address Cadd is also referred to as an individual command.

In the example of FIG. 10, the memory chip Die0 is designated as a leader, and for the memory chip Die0, “0” is set as the slot allocation number, by the power-ON read (POR). Further, the memory chips Die1 to DieN are designated as followers, and for the memory chips Die1 to DieN, 1 to N are set as the slot allocation numbers, respectively. Further, for the memory chips Die0 to DieN, the information on the clock cycle and the total number of slots is also set.

The control circuit 27 of each of the memory chips Die0 to DieN waits for reception of a peak control start command XXh transmitted from the memory controller 1. The peak control start command XXh is also not accompanied by the chip address Cadd. That is, upon receipt of the command XXh, each of the memory chips Die0 to DieN starts the peak control, irrespective of their chip addresses. That is, in the present embodiment, each memory chip 2 starts the peak operation control by receiving the peak control start command. That is, the peak control start command XXh is a broadcast command. When the peak operation control is required, the memory controller 1 is caused to transmit the peak control start command. Conversely, when the peak operation control is not required, the execution of the peak operation control can be prevented by suspending the transmission of the peak control start command from the memory controller 1. Note that when the control of the start of the peak operation control by the peak control start command is not required, the peak operation control may be started after a predetermined period of time elapses from the start of the power-ON read. Upon receipt of the peak control start command, the control circuit 27 of each of the chips Die0 to DieN provides the peak management information to the control device 41 of the logic control circuit 21 to cause the peak operation control to be started.

The control device 41 of the memory chip Die0 designated as a leader operates the clock oscillator 42, the frequency divider 43, the output circuit 44, the multiplexer 46, and the peak operation permission circuit 47. The clock oscillator 42 generates a clock, and the frequency divider 43 divides the frequency of the oscillation clock of the clock oscillator 42 by the frequency division number designated in accordance with the frequency division cycle and outputs the clock CK. As shown in FIG. 10, the output circuit 44 outputs the clock CK via the terminal /WP. The terminals /WP of the memory chips Die0 to DieN are connected to each other, and the clock CK from the memory chip Die0 as a leader is provided to the terminals /WP of the memory chips Die1 to DieN as followers. The multiplexer 46 of the memory chip Die0 as a leader outputs the clock CK from the frequency divider 43 to the peak operation permission circuit 47.

The control device 41 of each of the memory chips Die1 to DieN designated as followers operates the frequency divider 43, the multiplexer 46, and the peak operation permission circuit 47. In each of the memory chips Die1 to DieN, the input circuit 45 receives the clock CK input via the terminal /WP and provides the received clock CK to the multiplexer 46. The multiplexer 46 of each of the memory chips Die1 to DieN outputs the clock CK received by the input circuit 45 to the peak operation permission circuit 47.

Thus, a common clock CK is input to the peak operation permission circuit 47 of each of the memory chips Die0 to DieN. The peak operation permission circuit 47 counts the clock CK while resetting the count value based on the total number of slots. In this manner, as shown in FIG. 10, slots 0 to N are set in sync with the clock CK. The peak operation permission circuit 47 generates the peak enable signal when the slot number matches the slot allocation number.

A shaded portion in FIG. 10 indicates a period in which the peak enable signal becomes active, and the peak operation permission circuit 47 of each of the memory chips Die0 to DieN generates the peak enable signal at a timing corresponding to each of the slots indicated by the slot numbers 0, 1, 2, . . . N, and provides the generated peak enable signal to the peak control circuit 27a. In this manner, the peak control circuit 27a of each of the memory chips Die0 to DieN performs the peak operation control for generating the peak current during a slot period corresponding to the allocated slot allocation number.

In the present embodiment, as described above, in the semiconductor storage device having a multi-chip configuration, a specific chip is designated as a leader and the other chips as followers, and all the chips use a clock generated by the leader to perform the peak operation control of each chip so that the peak current can be suppressed. Further, the memory cell array stores, in advance, the peak management information for the peak operation control, and thus, the peak management information does not need to be provided to the memory chip 2 from the memory controller 1. In addition, the peak operation control can be started by the peak control start command, and the peak operation control can be performed when required.

### Stuck Busy State

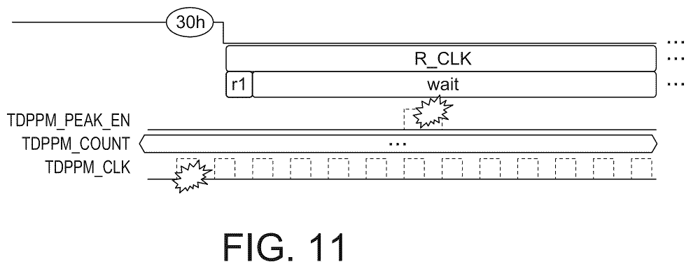

FIG. 11 is a view showing an example of TDPPM of a comparative example. FIG. 11 shows an operation of one memory chip of the memory chips Die1 to DieN designated as followers.

As shown in FIG. 11, a failure occurs in the clock CK (signal TDPPM_CLK system). The failure in the signal TDPPM_CLK system is, for example, a failure in a clock CK path from a leader to followers. A failure in a signal TDPPM_CLK path is, for example, a connection failure of the terminal /WP, adhesion of debris at the time of manufacturing, or the like.

A command 30h is a command for starting read operation. The waveform becomes an L level by the command 30h. Note that the timing of the command 30h is almost the same among all the memory chips Die0 to DieN. Further, the command is not limited to the command for starting read operation, and is preferably, for example, a command for starting operation that generates a current peak.

An R_CLK indicates that read operation proceeds by the internal clock generated in the chip.

At the timing at which r1 elapses, the read operation of the memory chip designated as a follower is suspended under TDPPM. A wait state in the R_CLK is a state in which the read operation is suspended while waiting for the signal TDPPM_CLK.

Since a peak enable signal TDPPM_PEAK_EN does not become an H level, the wait state continues. In this case, the suspended read operation cannot be resumed and thus, the memory chip continuously operates for the read operation, thereby getting stuck in a busy state, resulting in a critical failure.

Thus, a time limit (adding a timer function) for receiving the signal TDPPM_CLK is provided so as to avoid from getting stuck in a busy state due to the failure of the signal TDPPM_CLK system.

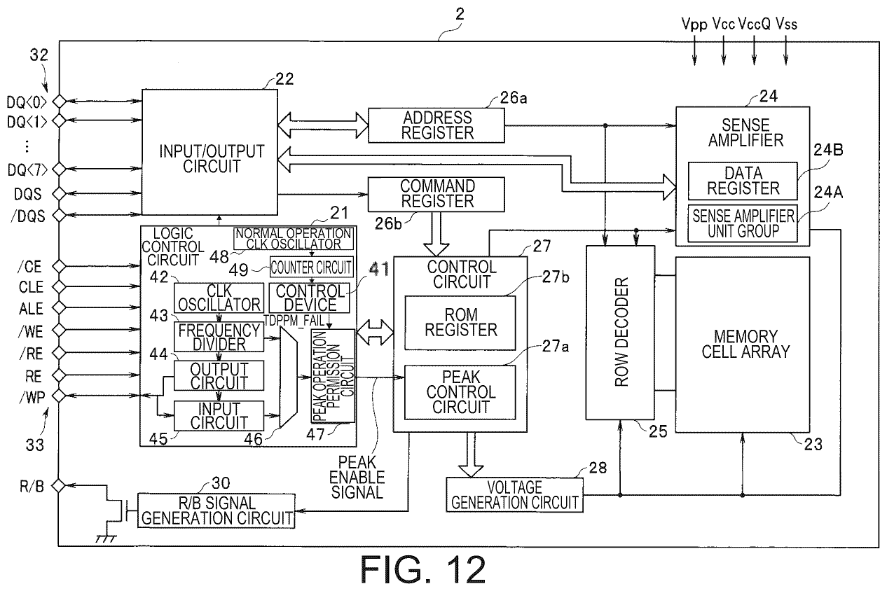

FIG. 12 is a block diagram showing a configuration example of the nonvolatile memory of the first embodiment.

The logic control circuit 21 further includes a normal operation clock oscillator 48 and a counter circuit 49.

The normal operation clock oscillator 48 generates an internal clock generated inside the chip, which differs from the signal TDPPM_CLK, and outputs the generated internal clock to the counter circuit 49.

The counter circuit 49 counts the internal clock input from the normal operation clock oscillator 48. The counter circuit 49 outputs the count value to the control device 41.

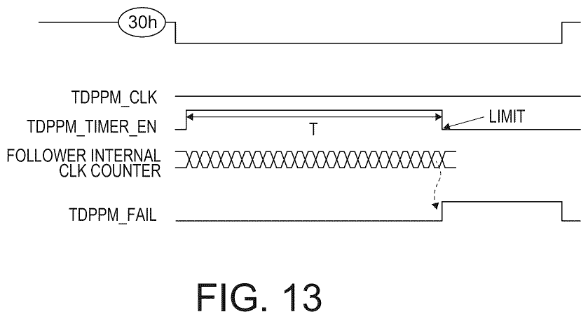

The control device 41 determines whether the memory chip properly operates under TDPPM and outputs the determination result. The control device 41 compares the count value input from the counter circuit 49 and a limit of a timer signal (TDPPM_TIMER_EN). The timer signal becomes an H level during a predetermined period of time T that is preset. The start timing of the predetermined period of time T is, for example, the timing at which operation is instructed. The end timing of the predetermined period of time T is referred to as a limit of the timer signal. Note that the details of the predetermined period of time T will be described later with reference to FIG. 13.

When the count value reaches the limit of the timer, the control device 41 generates a fail signal (signal TDPPM_FAIL) and outputs the generated fail signal to the peak operation permission circuit 47. The fail signal is a signal indicating that the wait state in which the read operation is suspended under TDPPM continued for a certain period of time.

The peak operation permission circuit 47 generates a forced resume signal based on the fail signal input from the control device 41. The forced resume signal is a signal that forcibly resumes the peak operation independent of the TDPPM operation. The peak operation permission circuit 47 generates the forced resume signal at the timing of receiving an input of the fail signal. The peak operation permission circuit 47 outputs the generated forced resume signal to the peak control circuit 27a.

When the peak control circuit 27a does not execute the partial operation (peak operation) that generates the current peak, within the predetermined period of time T after the operation is instructed, the peak control circuit 27a executes the partial operation that generates the current peak, after the predetermined period of time T elapses. More specifically, when the count value of the internal clock reaches the count value corresponding to the predetermined period of time T, the control device 41 causes the peak control circuit 27a to execute the partial operation that generates the current peak, after the predetermined period of time T elapses. More specifically, the control device 41 designates the timing after the predetermined period of time T elapses to the peak operation permission circuit 47 irrespective of the timing corresponding to the specific time slot, so as to cause the peak control circuit 27a to execute the partial operation that generates the current peak, after the predetermined period of time T elapses.

FIG. 13 is a view showing an example of TDPPM of the first embodiment.

The signal TDPPM_CLK continues to be at an L level due to a failure.

The limit is slightly longer than the maximum wait time of suspension under TDPPM. That is, the predetermined period of time T is longer than a time period corresponding to one cycle of a slot number of time slots. For example, when 16 memory chips are provided and one memory chip is shifted in a wait state by 1 μs, the maximum wait time of suspension under TDPPM is 16 μs, and the limit is (16+α) μs. The α is any set time and is, for example, around 1 μs.

The start timing of the predetermined period of time T is, for example, the timing at which operation is instructed. More specifically, the start timing of the predetermined period of time T is, for example, the timing at which a busy state starts. The start of the busy state is the timing at which the waveform becomes an L level by the command 30h. However, the start timing of the predetermined period of time T is not limited to the timing at which the busy state starts, and may be, for example, the timing at which the suspension starts. The start of the suspension is the timing (timing at which r1 elapses shown in FIG. 11) at which the wait state starts.

The counter circuit 49 counts the internal clock. If the signal TDPPM_CLK does not arrive by the limit of the timer from the start of the busy state, the control device 41 outputs the fail signal (signal TDPPM_FAIL). The peak operation permission circuit 47 generates the forced resume signal for the memory chip as a follower where a failure occurs, after the limit of the timer. In this manner, the memory chip as a follower where the failure occurs is automatically excluded from the operation mode under TDPPM and the read operation is forcibly resumed (normal operation is performed). As a result, getting stuck in a busy state can be avoided. The other memory chips where no failure occurs operate under TDPPM.

Further, when two or more memory chips are determined to be failed, for the two or more memory chips, read operation is concurrently performed.

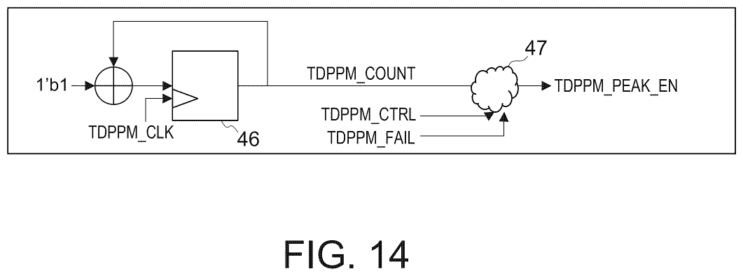

FIG. 14 is a view showing an example of paths of signals of the first embodiment.

The peak operation permission circuit 47 counts the signal TDPPM_CLK input via the multiplexer 46 so as to recognize the current slot number. The peak operation permission circuit 47 generates the peak enable signal TDPPM_PEAK_EN in sync with the timing at which the current slot number reaches the slot allocation number. The memory chip operates under TDPPM in such a manner.

The peak operation permission circuit 47 has a path for receiving the signal TDPPM_FAIL for performing normal operation, independent of the TDPPM operation. The control device 41 determines the failure of the signal TDPPM_CLK system based on the timer function. The control device 41 brings the signal TDPPM_FAIL into an H level, so that after the timer limit, the peak operation permission circuit 47 generates the forced resume signal. In this manner, after the timer limit, it is possible to cause the memory chip in which the failure occurs to forcibly resume the read operation.

As described above, according to the first embodiment, when the peak control circuit 27a does not execute the partial operation that generates the current peak, within the predetermined period of time T after the operation is instructed, the peak control circuit 27a executes the partial operation that generates the current peak, after the predetermined period of time T elapses. In this manner, it is possible to cause the memory chip in which a failure occurs to forcibly resume the read operation, after the timer limit. As a result, getting stuck in a busy state can be avoided.

Note that the memory chip Die0 as a leader is also determined by the control device 41 as to whether it is failed. That is, the memory chip Die0 as a leader is excluded from the TDPPM operation and performs normal operation when the own signal TDPPM_CLK cannot be detected.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a first pad;
a clock generation circuit configured to generate a first clock;
an output circuit configured to output the first clock through the first pad;
a designation circuit configured to designate, as a specific time slot, one of a plurality of time slots generated based on the first clock; and
a peak control circuit configured to execute a partial operation that generates a current peak, at a timing corresponding to the specific time slot, when an operation is instructed,
wherein when the peak control circuit does not execute the partial operation that generates the current peak, within a predetermined period of time after the operation is instructed, the peak control circuit executes the partial operation that generates the current peak, after the predetermined period of time elapses.

2. The semiconductor storage device according to claim 1, further comprising:
an internal clock generation circuit configured to generate an internal clock;
a counter circuit configured to count the internal clock; and
a control device configured to cause the peak control circuit to execute the partial operation that generates the current peak, after the predetermined period of time elapses, when a count value of the internal clock reaches a count value corresponding to the predetermined period of time.

3. The semiconductor storage device according to claim 2, wherein the control device, irrespective of the timing corresponding to the specific time slot, designates a timing after the predetermined period of time elapses to the designation circuit, so as to cause the peak control circuit to execute the partial operation that generates the current peak, after the predetermined period of time elapses.

4. The semiconductor storage device according to claim 1, wherein the predetermined period of time is longer than a time period corresponding to one cycle of a slot number of the time slots.

5. The semiconductor storage device according to claim 1, wherein the peak control circuit holds execution of the partial operation that generates the current peak until the timing corresponding to the specific time slot.

6. The semiconductor storage device according to claim 1, wherein the clock generation circuit, the output circuit, the designation circuit, and the peak control circuit start operations upon receipt of a first command.

7. The semiconductor storage device according to claim 6, wherein the output circuit operates when designated as a leader, and does not operate when designated as a follower irrespective of reception of the first command.

8. The semiconductor storage device according to claim 2, wherein the predetermined period of time is longer than a time period corresponding to one cycle of a slot number of the time slots.

9. The semiconductor storage device according to claim 3, wherein the predetermined period of time is longer than a time period corresponding to one cycle of a slot number of the time slots.

10. The semiconductor storage device according to claim 5, wherein the predetermined period of time is longer than a time period corresponding to one cycle of a slot number of the time slots.

11. The semiconductor storage device according to claim 6, wherein the predetermined period of time is longer than a time period corresponding to one cycle of a slot number of the time slots.

12. The semiconductor storage device according to claim 7, wherein the predetermined period of time is longer than a time period corresponding to one cycle of a slot number of the time slots.
